(19) United States
(12) Patent Application Publication
(10) Pub. No.: US 2013/0251950 A1
(43) Pub. Date: Sep. 26, 2013

(54) SILICON WAFER

(71) Applicant: GLOBALWAFERS JAPAN CO., LTD., Kitakanbara-gun (JP)

(72) Inventor: Yuri Kaneda, Hadano-shi (JP)

(73) Assignee: GlobalWafers Japan Co., Ltd., Kitakanbara-gun (JP)

(21) Appl. No.: 13/837,363

(22) Filed: Mar. 15, 2013

(30) Foreign Application Priority Data
Mar. 26, 2012 (JP) 2012-069258

(51) Int. Cl. C30B 29/68; C30B 29/06

(52) U.S. Cl. CPC C30B 29/68; C30B 29/06
USPC 428/149

(57) ABSTRACT

A silicon wafer is provided in which a dislocation is less likely Lo be generated originating from an oxide precipitate in a semiconductor device forming process, and a gettering effect with respect to Cu is increased. A silicon wafer 1 is characterized in that a surface layer portion 1a from a surface to a depth of at least 5 μm has an LSTD density of less than 1.0/cm², and that in a bulk portion 1b except the surface layer portion 1a, planar oxide precipitates 2a and polyhedral oxide precipitates 2b having a scattered light intensity of 3000 to 5000 a.u., and a density of 1.0×10⁹ to 6.0×10⁹ (particles/cm³) are each intermingled and grown, and a density ratio of the planar oxide precipitate to polyhedral oxide precipitate is represented by (planar oxide precipitate:polyhedral oxide precipitate=X: (100-X), where X is 10 to 40).

### BACKGROUND OF THE INVENTION

1. Field of the Invention

The present invention relates to a silicon wafer which is suitably used as a substrate for forming a semiconductor device.

2. Description of the Related Art

It is known that a silicon wafer (hereinafter may simply be referred to as wafer) grown by the Czochralski method (hereinafter maybe referred to as CZ method), includes Grown-in defects, such as COP (Crystal Originated Particle). It is known that if there is such a defect near a surface (surface layer portion from the surface to at least a depth of 5 μm) of the wafer to be a semiconductor device forming region, device properties, such as withstanding pressure of oxide-film, deteriorate. Further, it is said that an oxide precipitate (BulkMicro Defect: hereinafter maybe referred to as BMD) growing in a bulk portion of the wafer serves as a gettering site of impurities diffused in the surface layer portion in a later semiconductor device forming process and increases intensity of the wafer.

Then, in order to aim at reducing COP in the surface layer portion and promoting the growth of BMD in the bulk portion, a method of heat-treating the wafer at a high temperature is generally known (for example, Japanese Patent Application Publication (kokai) No. 2006-261632 (Patent Literature 1)). It should be noted that BMD formed by such a method mainly has a planar shape or a polyhedral shape, and these each have an advantage and a technical problems.

For example, in order to solve a problem that BMD having the shape of a polyhedron (hereinafter referred to as polyhedral oxide precipitate) provides a low gettering effect with respect to Cu, Japanese Patent Application Publication (kokai) No. 2005-50942 (Patent Literature 2) discloses a silicon wafer in which 1×10⁸/cm³or more BMD having the shape of a plane (hereinafter referred to as planar oxide precipitate) instead of polyhedral oxide precipitate are formed inside the wafer (bulk portion).

Further, as for the planar oxide precipitate, in order to solve a problem that when an LSA (Laser Spike Anneal) process is performed in a device process (semiconductor device forming process), a dislocation is easily generated originating from the oxide precipitate, Japanese Patent Application Publication (kokai) No. 2011-165812 (Patent Literature 3) discloses a silicon wafer in which polyhedral oxide precipitates predominantly grow rather than planar oxide precipitates.

However, since the planar oxide precipitates are formed in the bulk portion at a high density in the silicon wafer disclosed in Patent Literature 2, there is a problem that a dislocation is easily generated originating from the oxide precipitate in the device process as described in Patent Literature 3, for example.

Further, as for the silicon wafer disclosed in Patent Literature 3, since the polyhedral oxide precipitates predominantly grow rather than the planar oxide precipitates, a dislocation is less likely to be generated originating from the oxide precipitate in a device process. However, there is a problem that the gettering effect with respect to Cu is low as described in Patent Literature 2.

Therefore, there is desire to develop a silicon wafer which has the conflicting advantages and an advantage only among the technical problems.

### SUMMARY OF THE INVENTION

The present invention arises in view of the above-mentioned situation, and aims at providing a silicon wafer in which a dislocation is less likely to be generated originating from an oxide precipitate in a semiconductor device forming process and an increased gettering effect with respect to Cu is obtained.

The silicon wafer in accordance with the present invention is characterized in that a surface layer portion from a surface to a depth of at least 5 μm has an LSTD (Laser Scattering Topography Defect) density of less than 1.0/cm², and that in a bulk portion except the above-mentioned surface layer portion, planar oxide precipitates and polyhedral oxide precipitates having a scattered light intensity of 3000 to 5000 a.u., and a density of 1.0×10⁹ to 6.0×10⁹ (particles/cm³) are intermingled and grown, and a density ratio of the above-mentioned planar oxide precipitate to polyhedral oxide precipitate is represented by (planar oxide precipitate:polyhedral oxide precipitate=X: (100-X), where X is 10 to 40).

It is preferable that the above-mentioned surface layer portion comprises a device forming layer from the surface to a depth of 2 to 5 μm and a device non-forming layer which is provided between the above-mentioned device forming layer and the above-mentioned bulk portion, has a thickness of 5 to 15 μm, and does not allow the above-mentioned planar oxide precipitate or polyhedral oxide precipitate to grow.

According to the present invention, the silicon wafer is provided in which a dislocation is less likely to be generated originating from the oxide precipitate in the semiconductor device forming process and the increased gettering effect with respect to Cu is obtained.

### BRIEF DESCRIPTION OF THE DRAWING

FIG. 1 is a schematic sectional view showing a structure of a silicon wafer in accordance with the present invention.

FIG. 2 is a graph showing an example of a temperature sequence in heat treatment in accordance with the present invention.

### DESCRIPTION OF THE PREFERRED EMBODIMENTS

Hereinafter, a preferred embodiment of the present invention will be described in detail with reference to the drawings etc.

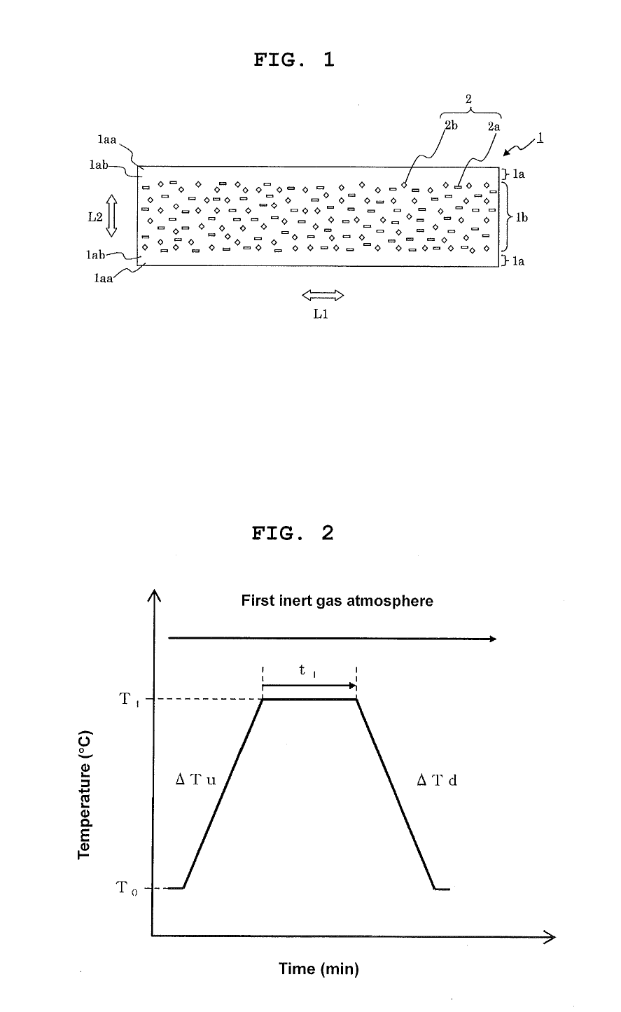

FIG. 1 is a schematic sectional view showing a structure of a silicon wafer in accordance with the present invention.

A silicon wafer 1 in accordance with the present invention is such that surface layer portions 1a from a surface to a depth of at least 5 μm have an LSTD density of less than 1.0/cm², a bulk portion 1b except the above-mentioned surface layer portions 1a has a scattered light intensity of 3000 to 5000 a.u., and oxide precipitates 2 are grown to have a density of 1.0×10⁹ to 6.0×10⁹ (particles/cm³) by subjecting the silicon wafer 1 to a BMD precipitating heat treatment to be set forth later. The oxide precipitates 2 include planar oxide precipitates 2a and polyhedral oxide precipitates 2b which are each intermingled and grown diametrically (transverse direction L1) and in a thickness direction L2 of the bulk portion 1b, and a density ratio of the above-mentioned planar oxide precipitate 2a to polyhedral oxide precipitate 2b is represented by (planar oxide precipitate:polyhedral oxide precipitate=X: (100-X), where X is 10 to 40).

As for the silicon wafer in accordance with the present invention, since the oxide precipitate 2 as described above is grown, a dislocation is less likely to be generated originating from the oxide precipitate in a semiconductor device forming process, and a gettering effect with respect to Cu is high.

That is, both the planar oxide precipitate 2a and polyhedral oxide precipitate 2b have a scattered light intensity of 3000 to 5000 a.u. and provide a density of 1:0×10⁹to 6.0×10⁹ (particles/cm³), so that the presence of the oxide precipitate 2 (especially planar oxide precipitate 2a) prevents the generation of distortion in the bulk portion 1b.

“Scattered light intensity” herein is a parameter which indicates a size of the oxide precipitate 2. When the scattered light intensity is high, it means that the size of the oxide precipitate 2 is large. This scattered light intensity and the above-mentioned density can be measured by an IR tomography apparatus (MO-411, manufactured by Raytex Corporation, Japan).

Thus, since the scattered light intensity and the density are within the above-mentioned ranges, it is possible to inhibit the generation of distortion in the bulk portion 1b. Therefore, in the semiconductor device forming process, it is possible to prevent a dislocation from being generated originating from the oxide precipitate 2 (especially planar oxide precipitate 2a).

Further, since X is 10 to 40 when the density ratio between the planar oxide precipitate 2a and the polyhedral oxide precipitate 2b is represented by (planar oxide precipitate:polyhedral oxide precipitate=X: (100-X)), it is possible to increase the gettering effect with respect to Cu.

The density ratio herein shows a ratio (A/(A+B)=X) when a sum (A+B) obtained by summing a density A measured only specifying the planar oxide precipitates 2a and a density B measured only specifying the polyhedral oxide precipitates 2b by the IR tomography apparatus (MO-411, manufactured by Raytex Corporation, Japan) is set to 100.

When the above-mentioned scattered light intensity is less than 3000 a.u., the gettering effect with respect to Cu is reduced. When the above-mentioned scattered light intensity exceeds 5000 a.u. the gettering effect with respect to Cu is increased. However, a dislocation is likely to be generated originating from the oxide precipitate 2 (especially planar oxide precipitate 2a) in the semiconductor device forming process.

When the above-mentioned density is less than 1.0×10⁹ (particles/cm³), which is low, a dislocation is less likely to be generated originating from the oxide precipitate 2 (especially planar oxide precipitate 2a). However, the gettering effect with respect to Cu may be reduced. When the above-mentioned density exceeds 6.0×10⁹ (particles/cm³), which is high, the gettering effect with respect to Cu increases. However, a dislocation is likely to be generated originating from the oxide precipitate 2 (especially planar oxide precipitate 2a).

It is preferable that the above-mentioned density is 3.0×10⁹ to 5.0×10⁹ (particles/cm³).

By choosing such a range of density, it is certainly possible to prevent a dislocation from being generated originating from the oxide precipitate in the semiconductor device forming process, and obtain the increased gettering effect with respect to Cu.

In the above-mentioned density ratio, when X is less than 10, the gettering effect with respect to Cu is reduced, because the planar oxide precipitate 2a decreases. When the above-mentioned X exceeds 40, a dislocation is likely to be generated originating from the planar oxide precipitate 2a, because the planar oxide precipitate 2a increases.

It is preferable that the above-mentioned surface layer portion 1a comprises a device forming layer 1aa from the surface to a depth of 5 μm and a device non-forming layer 1ab which is provided between the above-mentioned device forming layer 1aa and the above-mentioned bulk portion 1b, has a thickness of 5 to 15 μm, and does not allow the above-mentioned planar oxide precipitate 2a or polyhedral oxide precipitate 2b to grow.

Usually, the device forming layer used in the semiconductor device forming process is a region from the surface to a depth of 2-5 μm. In addition, when the device non-forming layer 1ab is provided between the device forming layer 1aa and the bulk portion 1b, the layer 1ab having a thickness of 5 to 15 μm and not allowing the above-mentioned planar oxide precipitate 2a or polyhedral oxide precipitate 2b to grow, even if a dislocation is generated originating from the oxide precipitate 2 (especially planar oxide precipitate 2a), it is possible to inhibit the dislocation from spreading over the device forming layer 1aa.

It is preferable that an oxygen concentration of the above-mentioned device non-forming layer lab is 0.8×10¹⁸ to 1.2×10¹⁸ atoms/cm³.

By choosing such a range of oxygen concentration, it is possible to further increase the gettering effect with respect to Cu. Since the oxygen concentration of the above-mentioned device non-forming layer 1ab increases, very few planar oxide precipitates which do not affect a semiconductor device property precipitate in this layer, and it is thought that the precipitates draw Cu in the device forming layer 1aa towards the hulk portion 1b, to thereby further increase the effect of gettering the planar oxide precipitates 2a in the bulk portion 1b.

It is preferable that the oxygen concentration of the above-mentioned device forming layer 1aa is lower than the oxygen concentration of the above-mentioned device non-forming layer 1ab, and is 0.4×10¹⁸ to 0.8×10¹⁸ atoms/cm³.

By choosing such a range of oxygen concentration, it is possible to prevent BMD from precipitating in the device forming layer 1aa.

Next, a method of manufacturing the above-mentioned silicon wafer in accordance with the present invention will be described.

The silicon wafer in accordance with the present invention can be manufactured by the following method.

A silicon wafer which is sliced from a silicon single crystal grown by the CZ method and has an oxygen concentration of 1.2×10¹⁸ atoms/cm³ or more, at least its semiconductor device forming side being mirror polished, is placed for treatment in a reaction chamber held at a temperature of 700° C. or less. In a non-oxidizing gas atmosphere, the temperature is raised from the above-mentioned treatment temperature to the maximum achievable temperature of 1100 to 1250° C. at a temperature rise rate of 2.0° C./minute or less, and the above-mentioned maximum achievable temperature is kept for 30 minutes to 2 hours.

It should be noted that the above-mentioned non-oxidizing gas atmosphere includes a nitrogen gas atmosphere, a hydrogen gas atmosphere, and an inert gas atmosphere (preferably argon gas atmosphere).

Further, adjustment of the density ratio between the above-mentioned planar oxide precipitate and the polyhedral oxide precipitate is carried out by adjusting the above-mentioned temperature rise rate.

Growing of the silicon single crystal by the CZ method is carried out by a well-known method. In particular, using a well-known single crystal growing apparatus, a seed crystal is brought into contact with a surface of a silicon melt, the seed crystal is pulled up while rotating the seed crystal and a quartz crucible, and a neck portion and a larger diameter portion which is enlarged to have a desired diameter are formed. Then, while maintaining the desired diameter, a straight cylindrical portion is formed by controlling a V/G value (V: pull rate, G: average of temperature gradients in a crystal in the direction of a raising axis in a temperature range from melting point of silicon to 1300␣) of a central axis portion of the crystal. Subsequently, a reduced diameter portion whose diameter is smaller than the desired diameter is formed, and the above-mentioned reduced diameter portion is cut out of the silicon melt. Further, adjustment of the oxygen concentration of the above-mentioned silicon single crystal to be grown is performed by a well-known method by adjusting a number of revolutions of the quartz crucible, furnace pressure, heater temperature, etc.

As for growing of the above-mentioned silicon single crystal, it is preferable that the straight cylindrical portion is formed by controlling the V/G value to be a predetermined value (for example, 0.25 to 0.35 mm²/° C.·min) so that the central axis portion of the crystal may be a V-rich region.

When controlling the V/G value to be a predetermined value (for example, 0.10 to 0.20 mm²/° C.·min) so that the central axis portion of the crystal may be a defect-free region, it is possible to manufacture the silicon wafer which does not have a Grown-in defect in the whole surface. However, there is a problem that a silicon single crystal growing efficiency is reduced in this case. Further, since the oxygen concentration in the crystal tends to be low when forming the defect-free region, it may be difficult to grow the above-mentioned oxide precipitate 2 in the bulk portion.

Next, the thus obtained silicon single crystal is sliced into silicon wafers by a well-known method, and a silicon wafer in which at least a semiconductor device forming side is mirror polished is prepared. In particular, after slicing the silicon single crystal into the shape of a wafer by an annular saw blade, a wire saw, etc., planarization processes, such as beveling of the perimeter section, lapping, etching, mirror polishing, etc. are performed.

Heat treatment for the mirror-polished silicon wafer obtained as described above is carried out using a well-known upright thermal treatment apparatus.

FIG. 2 is a graph showing an example of a temperature sequence in heat treatment in accordance with the present invention.

Firstly, a plurality of the above-mentioned mirror-polished wafers held, in a sheet-fed mode, in a well-known vertical board (for example) are placed in the reaction chamber (of the well-known upright thermal treatment apparatus) kept at a temperature T₀ (preferably 700° C. or less); the temperature is increased to the maximum achievable temperature T₁ (hereinafter abbreviated to temperature T₁) of from 1100° C. to 1200° C. (inclusive) at a temperature rise rate ΔTu (2.0° C./min or less) in a non-oxidizing gas atmosphere; the chamber is kept at the above-mentioned temperature T₁ for 30 minutes to two hours (inclusive) (t₁). Then, the above-mentioned temperature T₁ is decreased to a temperature (for example, temperature T₀) for removing the wafer out of the above-mentioned reaction chamber at a temperature drop rate ΔTd.

When the oxygen concentration of the above-mentioned silicon single crystal to be grown is less than 1.2×10¹⁸ atoms/cm³, which is low, it may not be possible to grow the oxide precipitate of a desired size and density in the bulk portion.

When the treatment temperature in the reaction chamber in the above-mentioned heat treatment exceeds 700° C., a slip dislocation is likely to be generated in the wafer by a rapid temperature change from room temperature (clean room: about 25° C.), this is not preferred.

It is preferable that a lower limit of the above-mentioned treatment temperature is 300° C. or more in terms of productivity etc.

When the above-mentioned maximum achievable temperature is less than 1100° C., which is low, it may be difficult to reduce defects, such as COP (Crystal Originated Particle) existing in the surface layer portion. When the above-mentioned maximum achievable temperature exceeds 1250° C., which is high, a slip dislocation may be likely to be generated in the heat treatment.

When the above-mentioned temperature rise rate ΔTu exceeds 2.0° C./min, the planar oxide precipitates may decrease in the density ratio.

When the retention time (t₁) of the above-mentioned maximum achievable temperature is less than 30 minutes, the heat treatment time is short. Thus, it may be difficult to reduce COP etc. sufficiently in the surface layer portion. When the above-mentioned retention time (t₁) exceeds 2 hours, productivity falls and a slip dislocation is likely to be generated. Further, other faults, such as impurities contamination, may be generated.

It is preferable that the temperature for removing the wafer out of the above-mentioned reaction chamber in the above-mentioned heat treatment is 700° C. or less.

When the above-mentioned removal temperature exceeds 700° C., a slip dislocation is likely to be generated in the wafer by the rapid temperature change (drop) to room temperature (clean room: about 25° C.), this is not preferred.

It is preferable that a lower limit of the above-mentioned removal temperature is 300° C. or more in terms of productivity etc.

The temperature drop rate ΔTd at the above-mentioned maximum achievable temperature in the above-mentioned heat treatment is not particularly limited, if it is controlled to be a rate at which a slip dislocation is not generated by the temperature change in the above-mentioned heat treatment. The rate at which the above-mentioned slip dislocation is not generated is 1 to 5° C./min for example.

### EXAMPLE

Hereinafter, the present invention will be described more particularly with reference to Example, however the following Example should not be construed as limiting the scope of the invention.

### [Examination 1]

Nitrogen doping (a silicon wafer piece having formed thereon nitride film was placed simultaneously with the placement of polysilicon in a quartz crucible) was performed by the CZ method; a number of revolutions of a quartz crucible and furnace pressure were adjusted; a V/G value (V: pull rate, G: average of temperature gradients in a crystal in the direction of a raising axis in a temperature range from melting point of silicon to 1300□) was controlled at from 0.28 to 0.32 mm²/° C.·min) to grow a plurality of silicon single crystals which were of N-type, a plane direction (100), in which a straight cylindrical portion was of a V-rich region, and oxygen concentrations were varied within a range of 1.2×10¹⁸ to 1.4×10¹⁸ atoms/cm³. Then, the straight cylindrical portion of the resulting ingot was sliced to obtain a plurality of disk-shaped sliced wafers having a diameter of 300 mm and V-rich regions whose oxygen concentrations were different.

The oxygen concentration is an average concentration by calculating those from the surface of the semiconductor device forming side of the sliced wafer to a depth of 1 micrometer measured using a secondary ion mass spectroscope (SIMS) (and so forth).

Next, a plurality of the resultant sliced wafers having different oxygen concentrations were subjected to a double-sided (front and back sides) lapping process. Further, they were subjected to an etching process by means of an acidic solution (where hydrofluoric acid (HF), nitric acid (HNO₃), acetic acid (CH₃COOH), and water (H₂O were mixed by a certain ratio). Finally, they were subjected to a double-sided mirror polish process.

Subsequently, 10 mirror-polished wafers each having different oxygen concentration were held in sheet-fed mode on a well-known vertical boat, and were supplied into the reaction chamber of a well-known upright thermal treatment apparatus. Further, in the heat treatment sequence shown in FIG. 2, the temperature rise rate ΔTu was changed within a range from 0.01 to 2.0° C./min to prepare a plurality of silicon wafers each having different sized (scattered light intensity) oxide precipitate growing in the bulk portion, different BMD density, and different density ratio of the planar oxide precipitate to the polyhedral oxide precipitate.

The other heat treatment conditions are as follows:
T₀: 700° C.
T₁: 1100° C.
t₁: 1 hour
ΔTd: 1° C./min. to 3° C./min

The wafers subjected to the above-mentioned heat treatment were evaluated for a defect density of the surface layer portion on the surface side to be the semiconductor device forming side. The evaluation of defect density was performed using an LSTD scanner MO601 manufactured by Raytex Corporation, Japan, by detecting the number of defects in each region from a measurement surface to a depth of 5 μm.

Further, the wafer subjected to the above-mentioned heat treatment was subjected to a BMD precipitating heat treatment (heat treatment at 780° C. for 3 hours, subsequent heat treatment at 1000° C. for 16 hours), then mirror polishing was performed down to the bulk portion (15 μm deep) of the wafer. Then, a size (dispersion intensity), a density, and a density ratio of the oxide precipitate of the polished side were evaluated using an IR tomography (MO-411, manufactured by Raytex Corporation, Japan).

Furthermore, using a sheet-fed type rapid-heating and rapid-cooling thermal processing apparatus, the wafer subjected to the above-mentioned heat treatment was placed in the reaction chamber held at 700° C., and subjected to rapid heating and rapid cooling thermal processing (Rapid Thermal Process: hereinafter referred to as RTP) in such a way that the temperature was increased to the maximum achievable temperature of 1350° C. at a temperature rise rate of 50° C./second, and held at 1350° C. for 15 seconds, then, the temperature was cooled to 700° C. at a temperature drop rate of 50° C./second. Subsequently, whether or not a dislocation was generated in a position at a depth of 5 μm from the surface of the semiconductor device forming side was determined by an X-ray topography apparatus (XRT300, manufactured by Rigaku Corporation, Japan).

After performing the above-mentioned RTP, determination of whether or not a dislocation was generated in the 5-micrometer deep position was carried out in such a manner that the semiconductor device forming side was removed down to a depth of 5 μm by mirror polishing and measured by the X-ray topography apparatus. Furthermore, the wafer subjected to the above-mentioned heat treatment was intentionally contaminated with Cu by means of a Cu (NO₃) ₂ solution.

Then, the surface layer portion of the surface to be the semiconductor device forming side was dissolved in fluoronitric acid, and a concentration of Cu contained in fluoronitric acid having dissolved therein the above-mentioned surface layer portion was evaluated by an ICP-MS (ICP-Mass Spectrometry: ICP mass analysis) apparatus.

Table 1 shows examination conditions and evaluation results in this examination.

TABLE 1

| | | | | Defect | | |
|---|---|---|---|---|---|---|
| | | Scattered | | density of | | |
| | | light | | surface layer | | Cu |
| | | intensity | BMD density | portion | Presence/absence | concentration |
| | X | (a.u) | (×10⁹/cm³) | (/cm²) | of dislocation | (×10¹⁰ atoms/cm²) |
| Comparative | 0 | 2000 | 3.1 to 5.9 | <1.0 | Absent | 12.1 to 13.4 |
| Example 1 | | | | | | |
| Comparative | 0 | 3000 | | <1.0 | Absent | |
| Example 2 | | | | | | |
| Comparative | 0 | 5000 | | <1.0 | Absent | |
| Example 3 | | | | | | |
| Comparative | 10.5 | 2300 | 4.2 to 4.5 | <1.0 | Absent | 7.2 |
| Example 4 | | | | | | |
| Example 1 | 10.0 | 3000 | 3.0 to 4.5 | <1.0 | Absent | 2.5 to 3.0 |
| Example 2 | 10.4 | 3800 | | <1.0 | Absent | |
| Example 3 | 10.3 | 4200 | | <1.0 | Absent | |
| Example 4 | 10.0 | 5000 | | <1.0 | Absent | |
| Comparative | 10.0 | 7200 | 2.1 to 2.4 | <1.0 | Present | 2.8 |
| Example 5 | | | | | | |
| Comparative | 26.2 | 2400 | 4.1 to 4.6 | <1.0 | Absent | 5.1 |
| Example 6 | | | | | | |
| Example 5 | 27.2 | 3200 | 4.1 to 5.1 | <1.0 | Absent | 1.5 to 1.8 |
| Example 6 | 26.4 | 3700 | | <1.0 | Absent | |
| Example 7 | 25.5 | 4200 | | <1.0 | Absent | |
| Example 8 | 25.4 | 5000 | | <1.0 | Absent | |
| Comparative | 26.0 | 6400 | 2.1 to 3.2 | <1.0 | Present | 1.2 |
| Example 7 | | | | | | |
| Comparative | 40.3 | 1200 | 5.1 to 6.0 | <1.0 | Absent | 4.1 |
| Example 8 | | | | | | |
| Example 9 | 40.0 | 3000 | 3.9 to 5.0 | <1.0 | Absent | 1.0 to 1.3 |
| Example | 39.5 | 3500 | | <1.0 | Absent | |
| 10 | | | | | | |
| Example | 39.2 | 4100 | | <1.0 | Absent | |
| 11 | | | | | | |
| Example | 40.0 | 5000 | | <1.0 | Absent | |
| 12 | | | | | | |
| Comparative | 39.5 | 6100 | 2.1 to 2.5 | <1.0 | Present | 0.9 |
| Example 9 | | | | | | |
| Comparative | 49.4 | 4300 | 3.5 to 3.8 | <1.0 | Present | 0.8 to 0.9 |
| Example 10 | | | | | | |
| Comparative | 54.3 | 2100 | 2.3 to 3.5 | <1.0 | Present | |
| Example 11 | | | | | | |

As can be seen from Table 1, when X is 10 to 40 and the scattered light intensity (a. u.) is 3000 to 5000 (Examples 1 to 12), it is seen that the defect density of the surface layer portion is less than 1.0/cm², no slip dislocations are generated, and a Cu concentration is low. On the other hand, when X is 0 (Comparative Examples 1 to 3), it is seen that the Cu concentration is high, even if the scattered light intensity (a. u.) is high. In contrast, when X is 10 or more, the Cu concentration decreases. However, when the scattered light intensity is less than 3000 a.u. (Comparative Examples 4, 6, and 8), it is seen that the Cu concentration is still high. Further, when the scattered light intensity exceeds 5000 a.u. (Comparative Examples 5, 7, and 9), and when X exceeds 40 (Comparative Examples 10 and 11), it is seen that a slip dislocation is generated.

In addition, as for samples subjected to the above-mentioned BMD precipitating heat treatment in Examples 1 to 12, the wafers were cleaved diametrically and polished diagonally (at an angle of 30 degrees to the surface). The thus polished surface was observed by SEM (Scanning Electron Microscope) and a thickness of the surface layer portion from the surface to an upper edge of the bulk portion was calculated to find 10 μm.

Further, the oxygen concentration of the surface layer portion of the above-mentioned polished side was measured using the secondary ion mass spectroscope (SIMS). As a result, the oxygen concentration of the surface layer portion from the surface down to 10 μm was 0. 4×10¹⁸ to 0.8×10¹⁸atoms/cm³. Furthermore, the defect density and BMD density of the surface layer portion were evaluated in a similar manner as described above. As a result, the defect density was less than 1. 0/cm², and the BMD density was a detection limit or less (around 3.0×10⁶/cm³ or less).

### [Examination 2]

The oxygen concentration at the time of growing the above-mentioned silicon single crystal was adjusted to 1.5×10¹⁸ to 1.8×10¹⁸ atoms/cm³, the maximum achievable temperature and heat treatment time in the above-mentioned heat treatment were adjusted, and others were similar to conditions in Examples 1 to 4. Under these conditions, silicon wafers were prepared in which the oxygen concentration of the region from the surface down to 5 μm was 0. 4×10¹⁸ to 0.8×10¹⁸ atoms/cm³ and the oxygen concentration of between a depth of 5 μm to 10 μm from the surface layer portion was 0.8×10¹⁸ to 1.2×10¹⁸.

As for the thus obtained silicon wafer, a number of defects in the region from the surface to a depth of 5 μm, a size (dispersion intensity) of the bulk portion (15 μm deep), a density, and a density ratio, the presence of a dislocation, and a Cu concentration were evaluated.

Table 2 shows examination conditions and evaluation results in this examination.

TABLE 2

| | | | | Defect | | |
|---|---|---|---|---|---|---|
| | | | | density of | | |
| | | | | surface | | |
| | | | | layer | | |
| | | Scattered light | BMD density | portion | Presence/absence | Cu concentration |
| | X | intensity (a.u) | (×10⁹/cm³) | (/cm²) | of dislocation | (×10¹⁰ atoms/cm²) |
| Example | 10.2 | 3000 | 2.8 to 4.4 | <1.0 | Absent | 1.8 to 2.0 |
| 13 | | | | | | |
| Example | 10.3 | 3800 | | <1.0 | Absent | |
| 14 | | | | | | |
| Example | 10.2 | 4300 | | <1.0 | Absent | |
| 15 | | | | | | |
| Example | 10.1 | 4700 | | <1.0 | Absent | |
| 16 | | | | | | |

As can be seen from Table 2, when the oxygen concentration of between a depth of 5 μm and 10 μm from the surface layer portion is 0.8×10¹⁸ to 1.2×10¹⁸ (Examples 13 to 16), it is seen that the Cu concentration decreases compared with Examples 1 to 4.

What is claimed is:

1. A silicon wafer in which a surface layer portion from a surface to a depth of at least 5 μm has an LSTD (Laser Scattering Topography Defect) density of less than 1.0/cm²,
in a bulk portion except said surface layer portion, a planar oxide precipitate and a polyhedral oxide precipitate (each) having a scattered light intensity of 3000 to 5000 a.u., and a density of 1.0×10⁹ to 6.0×10⁹ (particles/cm³) are intermingled and grown, and a density ratio of said planar oxide precipitate to polyhedral oxide precipitate is represented by (planar oxide precipitate:polyhedral oxide precipitate=X: (100-X), where X is 10 to 40).

2. A silicon wafer as claimed in claim 1, wherein said surface layer portion comprises a device forming layer from the surface to a depth of 2 to 5 μm and a device non-forming layer which is provided between said device forming layer and said bulk portion, has a thickness of 5 to 15 μm, and does not allow said planar oxide precipitate or polyhedral oxide precipitate to grow.
